(19) United States
(12) Patent Application Publication
(10) Pub. No.: US 2013/0332666 A1
(43) Pub. Date: Dec. 12, 2013

(54) INFORMATION PROCESSOR, INFORMATION PROCESSING METHOD, AND COMPUTER PROGRAM PRODUCT

(71) Applicant: Kabushiki Kaisha Toshiba, Tokyo (JP)

(72) Inventor: Kosuke Haruki, Tachikawa-shi (JP)

(73) Assignee: KABUSHIKI KAISHA TOSHIBA, Tokyo (JP)

(21) Appl. No.: 13/963,179

(22) Filed: Aug. 9, 2013

Related U.S. Application Data
(63) Continuation of application No. PCT/JP2013/057942, filed on Mar. 13, 2013.

(30) Foreign Application Priority Data
May 23, 2012 (JP) 2012-117111

(51) Int. Cl. G11C 7/10; G06F 12/08

(52) U.S. Cl. CPC G11C 7/1075; G06F 12/0806
USPC 711/104; 711/119

(57) ABSTRACT

According to one embodiment, an information processor configured to execute codes described in Open Computing Language (OpenCL) includes: a first cache; a second cache; a global memory; and an arithmetic module. The first cache is with local scope and configured to be capable of being referred to by all work items in one workgroup. The second cache is with global scope and configured to be capable of being referred to by all work items in a plurality of workgroups. The global memory is with global scope and configured to be capable of being referred to by all work items in a plurality of workgroups. The arithmetic module is configured to execute a code referring to the second cache as a scratch-pad memory.

### CROSS-REFERENCE TO RELATED APPLICATIONS

This application is a continuation of PCT international application Ser. No. PCT/JP2013/057942, filed on Mar. 13, 2013, which designates the United States, incorporated herein by reference, and which is based upon and claims the benefit of priority from Japanese Patent Application No. 2012-117111, filed on May 23, 2012, the entire contents of which are incorporated herein by reference.

### FIELD

Embodiments described herein relate generally to an information processor, an information processing method, and a computer program product.

### BACKGROUND

One of the conventional frameworks for parallel computing is Open Computing Language (OpenCL). The OpenCL attracts attention as a cross-platform framework in a heterogeneous environment where different processors such as a central processing unit (CPU) and a graphics processing unit (GPU) are used in combination.

The OpenCL uses four kinds of memories such as a global memory, a constant memory, a local memory, and a private memory as memories in a kernel. Out of these memories, the private memory is a register used in a work item and connected to each processor. The local memory is a cache memory allocated to each workgroup and capable of being read and written from all work items in one workgroup. The global memory is a memory allocated to all workgroups in common and capable of being read and written from all work items in all workgroups. The constant memory is a memory region allocated as a global memory region and capable of being read from all work items.

According to the specifications of the OpenCL, the OpenCL can also be used in a multiprocessor system having a multistage cache structure configured by a scratch-pad memory with global scope in addition to a scratch-pad memory with local scope, as a cache memory. However, it is impossible for an existing OpenCL to make a program so that the program specifically refers to the scratch-pad memory with global scope. Accordingly, it is impossible to specify the scratch-pad memory as intended by a programmer so as to improve program performance.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram of a schematic configuration of a memory-model processor-model specified in an existing OpenCL;

FIG. 2 is an exemplary model chart of a schematic configuration of tasks executed by each arithmetic module in the memory-model processor-model illustrated in FIG. 1;

FIG. 3 is an exemplary block diagram of a schematic configuration of the memory-model processor-model according to an embodiment;

FIG. 4 is an exemplary diagram of a code described in the existing OpenCL;

FIG. 5 is an exemplary diagram of a code described in OpenCL in the embodiment;

FIG. 6 is another exemplary diagram of a code described in the existing OpenCL;

FIG. 7 is still another exemplary diagram of a code described in the OpenCL in the embodiment;

FIG. 8 is an exemplary diagram of a code described when a scratch-pad memory with a local scope is used by 512 bytes, in the embodiment;

FIG. 9 is an exemplary flowchart illustrating the behavior of the OpenCL runtime or behavior of an OpenCL compiler when the code illustrated in FIG. 8 is interpreted by the existing OpenCL;

FIG. 10 is an exemplary flowchart illustrating the behavior of the OpenCL runtime or behavior of an OpenCL compiler when the code illustrated in FIG. 8 is interpreted by the OpenCL in the embodiment;

FIG. 11 an exemplary diagram of a code described when a scratch-pad memory with local scope is used by 128 bytes;

FIG. 12 is an exemplary flowchart illustrating the behavior of the OpenCL runtime or the behavior of the OpenCL compiler when a mode of CL_RUNTIME_STRICT_MODE is set for the OpenCL runtime; and

FIG. 13 is an exemplary flowchart illustrating the behavior of the OpenCL runtime or the behavior of the OpenCL compiler when a mode of CL_RUNTIME_NORMAL_MODE is set for the OpenCL runtime.

### DETAILED DESCRIPTION

In general, according to one embodiment, an information processor is configured to execute codes described in Open Computing Language (OpenCL). The information processor comprises: a first cache; a second cache; a global memory; and an arithmetic module. The first cache is with local scope and configured to be capable of being referred to by all work items in one workgroup. The second cache is with global scope and configured to be capable of being referred to by all work items in a plurality of workgroups. The global memory is with global scope and configured to be capable of being referred to by all work items in a plurality of workgroups. The arithmetic module is configured to execute a code referring to the second cache as a scratch-pad memory.

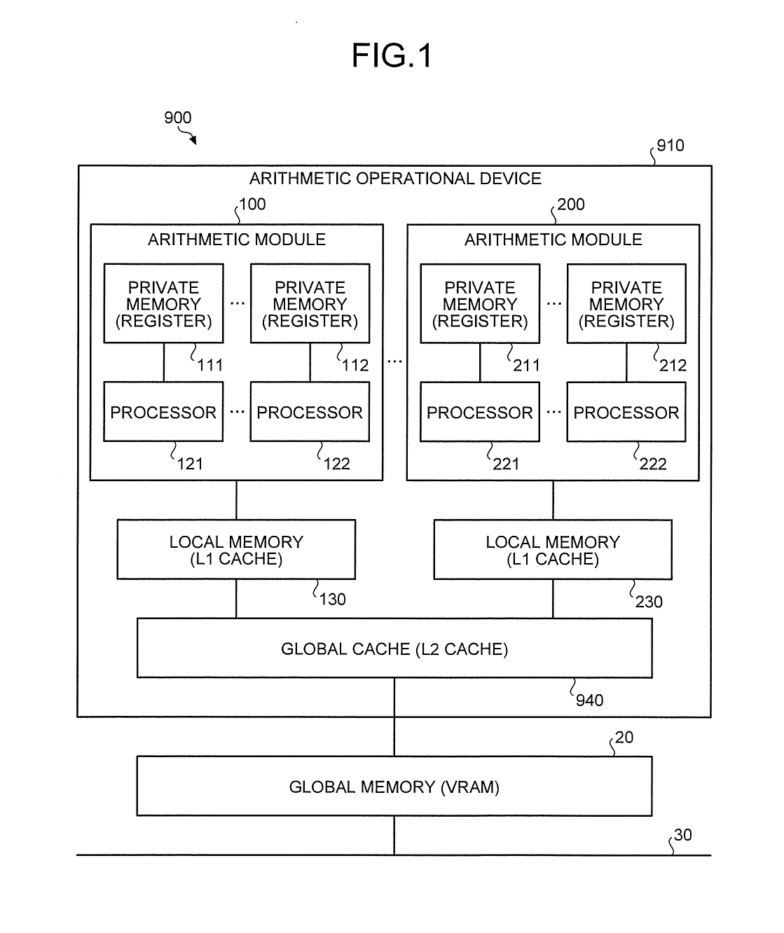

Hereinafter, in explaining an information processor, an information processing method, and a control program according to an embodiment, a memory-model processor-model specified in an existing OpenCL is explained. The OpenCL is a standard for software platform utilizing a processor capable of performing parallel operations, such as a graphics processing unit (GPU), as a general-purpose computing element. FIG. 1 is a block diagram illustrating the schematic configuration of a memory-model processor-model 900 specified in the existing OpenCL.

As illustrated in FIG. 1, the memory-model processor-model 900 employs a configuration in which arithmetic operational device 910 is connected to an expansion bus 30 via a global memory 20. The arithmetic operational device 910 may be a CPU, a GPU, or the like. As the global memory 20, a video random access memory (VRAM) or the like can be used. As the expansion bus 30, for example, an I/O serial interface such as a PCI Express (PCIe) is used.

The arithmetic operational device 910 comprises a plurality of arithmetic modules 100 and 200, local memories (L1 caches) 130 and 230 that are provided to the respective arithmetic modules 100 and 200, and a global cache (L2 cache) 940 provided to all of the arithmetic modules 100 and 200 in common.

Each of the arithmetic modules 100 and 200 employs a configuration in which a plurality of processors 121 and 122 provided with private memories 111 and 112, respectively, or a plurality of processors 221 and 222 provided with private memories 211 and 212, respectively, are arranged in parallel. The private memories 111 and 112 and the private memories 211 and 212 are registers each of which stores therein commands or information for processors 121 and 122 and processors 221 and 222, respectively, each of which is connected thereto.

Each of the local memories 130 and 230 in the arithmetic operational device 910 is an L1 cache (also referred to as a level 1 cache). The global cache 940 is an L2 cache (also referred to as a level 2 cache). That is, the memory-model processor-model 900 illustrated in FIG. 1 employs a multistage cache structure configured by the L1 cache and the L2 cache.

The local memory 130 (230) is capable of being read and written from all work items in a workgroup, the work items being executed in the arithmetic module 100 (200) connected to the local memory 130 (230). However, the work items executed in the arithmetic module 100 (200) cannot refer to the local memory 230 (130) connected to the other arithmetic module 200 (100). On the other hand, the global cache 940 is capable of being read and written from all work items in a workgroup, the work items being executed in all the arithmetic modules 100 and 200.

The global memory 20 is capable of being read and written from all work items in a workgroup, the work items being executed in all the arithmetic modules 100 and 200. The global memory 20 may be, for example, substituted with a constant memory.

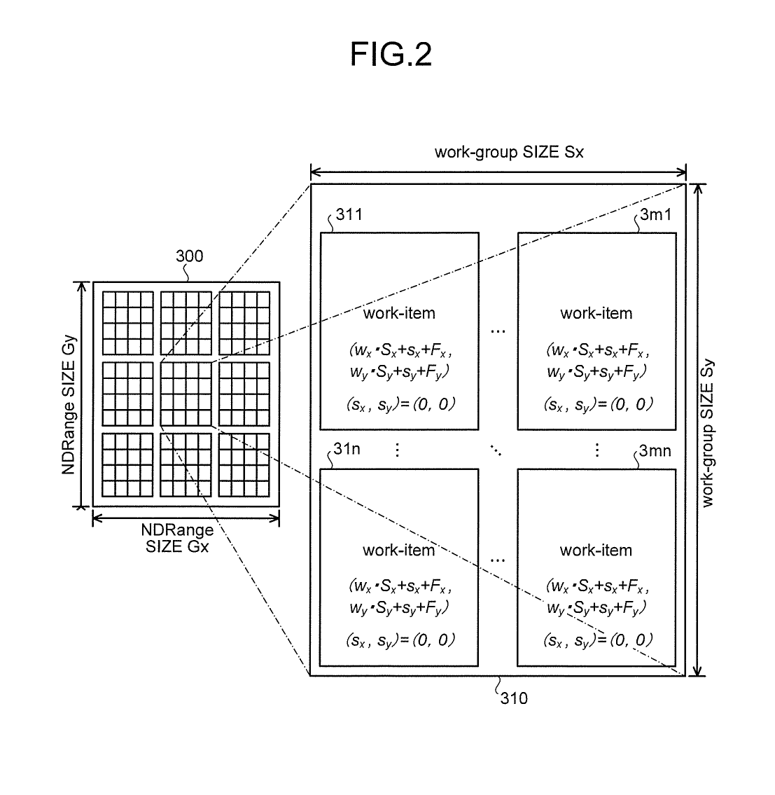

FIG. 2 is a model chart illustrating a schematic configuration of tasks executed by each of the arithmetic modules 100 and 200 in the memory-model processor-model 900 illustrated in FIG. 1. As illustrated in FIG. 2, on one of the arithmetic modules 100 and 200 (hereto, on the arithmetic module 100), work items in one workgroup 310 in an aggregation 300 of workgroups are executed. Each workgroup 310 is configured by an aggregation of a plurality of work items 311 to 3 nm. When the number of the work items 311 to 3 nm in the workgroup 310 is larger than the number of physical processors in the arithmetic module 100, the work items 311 to 3 nm are executed in the arithmetic module 100 while being scheduled.

A general GPU employs an architecture such that the L1 caches respectively connected to the arithmetic modules 100 and 200 are used as the local memories 130 and 230 and a VRAM is used for the global memory 20. In such a configuration, speeds for accessing the memories 130, 230 and the memory 20 are equivalent to speed for accessing the L1 cache and the VRAM, respectively. Accordingly, in order to improve the performance of a program described in the OpenCL (hereinafter, referred to as an OpenCL program), it has been common practice to describe code such that the local memories 130 and 230 are used as much as possible and the frequency of accessing the global memory 20 is reduced.

The number of the local memories 130 and 230 mounted on the arithmetic operational device 910 is generally small, and the size of each memory mounted is changed depending on specifications provided by a device vendor. As described above, in order to improve the performance of the OpenCL program, it is necessary to describe code in consideration of the sizes of the local memories 130 and 230. Whether the OpenCL program can be operated depends on whether the local memories 130 and 230 having sizes required are mounted on the arithmetic operational device 910. Accordingly, there has been a case that code described in the OpenCL that is the standard for cross-platform is operated in a device and not operated in other devices. In this case, there has been a case that it is necessary to change logical scope depending on the sizes of memories mounted on a piece of hardware (HW).

The tasks mentioned above may be brought about by the fact that the local memory in the OpenCL simultaneously has two meanings; that is, the logical meaning of the local memory capable of being referred only in a workgroup, and the physical meaning of the local memory associated with an arithmetic module.

The specifications of the existing OpenCL include a memory model that is a local memory for utilizing the L1 cache or equivalent (or a dedicated memory) as a scratch-pad memory, but no memory model for specifically utilizing the L2 cache or equivalent as a scratch-pad memory. Accordingly, in the existing OpenCL, there also exists a task that when sharing data among all the workgroups 310, it is necessary to access the local memory via the global memory whose access speed is comparatively slow.

In a device on which the L2 cache having a comparatively large size is mounted, a certain amount of data is cached in the L2 cache and hence, there exists the case that a certain level of device performance can be obtained on the average. However, there has been a case that a cache error occurs depending on operation conditions and the device performance becomes unstable.

Under such circumstances, the inventors have found that in order to obtain high performance in a stable manner, a mechanism for specifically utilizing a memory equivalent to the L2 cache in the same manner as the case of the local memory is required. In the following embodiment, new specifications to be added to the OpenCL are proposed.

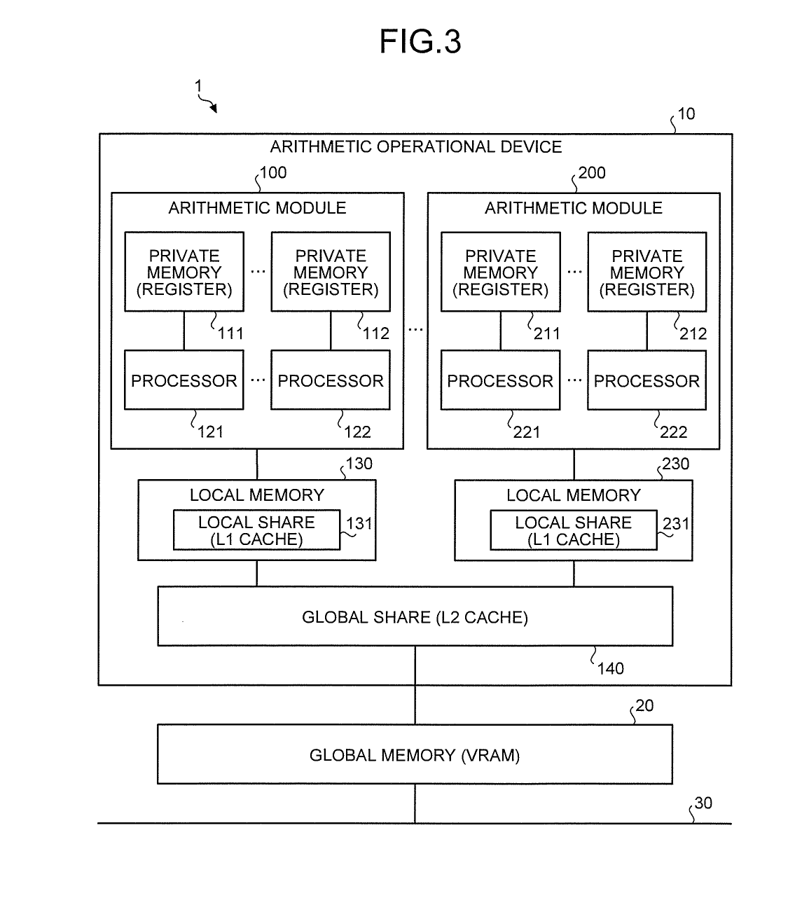

FIG. 3 is a block diagram illustrating the schematic configuration of a memory-model processor-model 1 according to the embodiment. In FIG. 3, the configurations identical to those illustrated in FIG. 1 are given same numerals and their repeated explanations are omitted.

As illustrated in FIG. 3, in the memory-model processor-model 1 in the embodiment, local shares 131 and 231 used as the L1 caches are respectively arranged in the local memories 130 and 230 with which an arithmetic operational device 10 is provided. Furthermore, a global share 140 used as the L2 cache is substituted for the global cache 940 used as the L2 cache. That is, in the OpenCL in the embodiment, two memory models such as the local shares 131 and 231 equivalent to the L1 caches and the global share 140 equivalent to the L2 cache are newly added, and these local shares 131 and 231, and the global share 140 are defined as cache memories that can be specifically utilized. The configurations other than above may be the same as those illustrated in FIG. 1.

Table 1 below illustrates the list of memory modifiers that can be described in the OpenCL in the embodiment. Here, Table 1 illustrates modifiers that are used for specifying local scope and global scope and can be described in the existing OpenCL, and modifiers that are used for specifying the local scope and the global scope and can be described in the OpenCL in the embodiment.

TABLE 1

| | Modifier | Scope | Physical allocation |
|---|---|---|---|
| Existing | _local | In a | L1 cache or equivalent |
| OpenCL | | Work-Group | (becomes an error when no |
| | | | memory is available) |
| | _global | Global | Global memory |
| OpenCL | _local | In a | L1 cache or global memory |
| according | | Work-Group | (Physical allocation is |
| to the | | | basically unrestricted. The |
| embodiment | | | logical scope is specified) |
| | _local_share | In a | L1 cache or equivalent (in the |
| | | Work-Group | mode of |
| | | | CL_RUNTIME_NORMAL_MODE, |
| | | | the memory may be allocated to |
| | | | the global memory if no memory |
| | | | is available) |
| | _global | Global | Global memory |
| | _global_share | Global | L2 cache or equivalent (in the |
| | | | mode of |
| | | | CL_RUNTIME_NORMAL_MODE, |
| | | | the memory may be allocated to |
| | | | the global memory if no memory |
| | | | is available) |

As illustrated in Table 1, the existing OpenCL uses only two memory modifiers; that is, the modifier of “_local” indicating the local memories 130 and 230, and the modifier of “_global” indicating the global memory 20. On the other hand, the OpenCL in the embodiment uses the modifier of “_local_share” indicating the local shares 131 and 231 corresponding to the L1 cache and the modifier of “_global_share” indicating the global share 140 corresponding to the L2 cache in addition to the modifiers used by the existing OpenCL. Furthermore, in addition to these two modifiers, the meaning of the modifier of “_local” used by the existing OpenCL is changed to the contents listed in Table 1.

To be more specific, the modifier of “_local_share” added defines the scratch-pad memory (L1 cache or equivalent) with the local scope. In the same manner as above, the modifier of “_global_share” added defines the scratch-pad memory (L2 cache or equivalent) with the global scope. Furthermore, the modifier of “_local” whose definition is changed specifies only the logical scope without restricting the physical allocation. Therefore, in the case of the configuration illustrated in FIG. 3, a physical allocation that code declared by the modifier of “_local” indicates may be any of the local memories 130 and 230, the global share 140, and the global memory 20.

As a flag for ensuring a buffer object specified by the modifier of “_global_share” in the global share (L2 cache) 140, the value of “CL_MEM_GLOBAL_SHARE” listed in Table 2 below is added. The value of “CL_MEM_GLOBAL_SHARE” is set to the argument of “cl_mem_flags” of the syntax of clCreateBuffer ( ).

TABLE 2

| cl_mem_flags | Explanations |
|---|---|
| CL_MEM_GLOBAL_SHARE | This flag is set to the argument of |
| | cl_mem_flags of the syntax of |
| | clCreateBuffer ( ) or the like. |
| | The memory is ensured in the |
| | global share. When OpenCL |
| | runtime is in the mode of |
| | CL_RUNTIME_NORMAL_MODE, |
| | the memory may be ensured |
| | in the global memory. |

Furthermore, as the mode of the OpenCL runtime or the mode of an OpenCL compiler, two modes listed in Table 3 below are defined. These modes specify the behavior of the OpenCL runtime toward the local shares 131 and 231, and the global share 140, and are set to the argument of “cl_runtime_mode” of the syntax of cl_runtime_mode. Here, the modes listed in Table 3 can also be utilized as a direction to the OpenCL compiler.

TABLE 3

| cl_runtime_mode | Explanations |
|---|---|
| CL_RUNTIME_NORMAL_MODE | The OpenCL runtime empha- |
| | sizes the compatibility of |
| | operations. When the intended |
| | physical allocation of the |
| | memory to the local share or |
| | the global share fail, the |
| | memory is ensured in the |
| | global memory to continue |
| | operations. |
| CL_RUNTIME_STRICT_MODE | The OpenCL runtime empha- |
| | sizes program performance. |
| | When memory ensuring in the |
| | local share or the global |
| | share fails, operations are |
| | finished as an error so that |
| | the failure becomes a hint in |
| | tuning the program performance. |

As listed in Table 1 also, in the case where the mode of “CL_RUNTIME_NORMAL_MODE” is set to the OpenCL runtime, when the size of memory in the L1 cache or the L2 cache is insufficient in being declared the modifier of “_local_share” or “_global_share”, the physical allocation of the cache memory to the global memory 20 may be accepted.

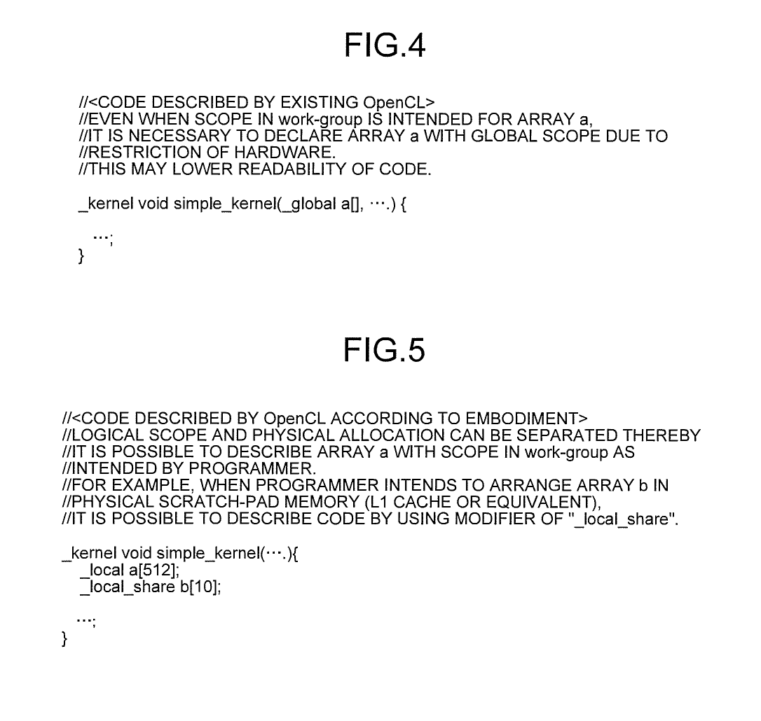

Subsequently, code described in the OpenCL in the embodiment is explained while comparing with code described in the existing OpenCL. FIG. 4 and FIG. 5 intend an array a of 512 bytes to be referred only in a workgroup, and each of FIG. 4 and FIG. 5 is a view illustrating one example of code in the case where the array a is not able to be arranged in a physical scratch-pad memory (L1 cache or equivalent) depending on the restriction of hardware. FIG. 4 is a view illustrating one example of code described in the existing OpenCL. FIG. 5 is a view illustrating one example of code described in the OpenCL in the embodiment.

As illustrated in FIG. 4, when the existing OpenCL is used, the array a cannot be declared with a scope in a workgroup and hence, it has been necessary to declare the array a with global scope (_global a[ ]). Accordingly, the code described in the existing OpenCL has been low in readability. In contrast, as illustrated in FIG. 5, when the OpenCL in the embodiment is used, a logical scope and a physical scope can separately be declared and hence, it is possible to declare the array a with scope in a workgroup (_local a[512]) as intended by a programmer. Furthermore, when a programmer intends to arrange an array b in the physical scratch-pad memory (L1 cache or equivalent), it is possible to describe the code by using the modifier of “_local_share”.

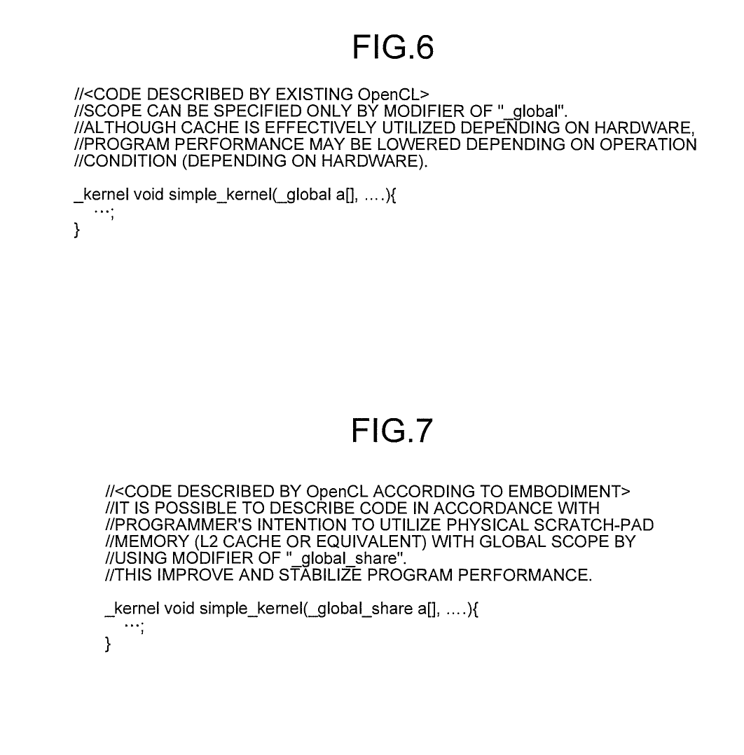

Next, each of FIG. 6 and FIG. 7 illustrates a code in the case where, although the array a is required to be shared and referenced among all workgroups, it is necessary to arrange the array a in a physical allocation capable of being accessed at high speed because read and write may be performed frequently.

FIG. 6 is a view illustrating one example of code described in the existing OpenCL. FIG. 7 is a view illustrating one example of code described in the OpenCL in the embodiment.

As illustrated in FIG. 6, when the existing OpenCL is used, a physical allocation can be specified only by scope with the modifier of “_global” (_global a[ ]). Therefore, although a cache memory is effectively utilized depending on a hardware configuration, there exists a possibility that program performance is lowered or becomes unstable depending on operation conditions. In contrast, as illustrated in FIG. 7, when the OpenCL in the embodiment is used, it is possible to describe the code (_global_share a[ ]) in accordance with the programmer's intention to utilize a physical scratch-pad memory (L2 cache or equivalent) with a global scope by using the modifier of “_global_share”. Accordingly, it is possible not only to improve program performance but also to ensure the stability of the program performance.

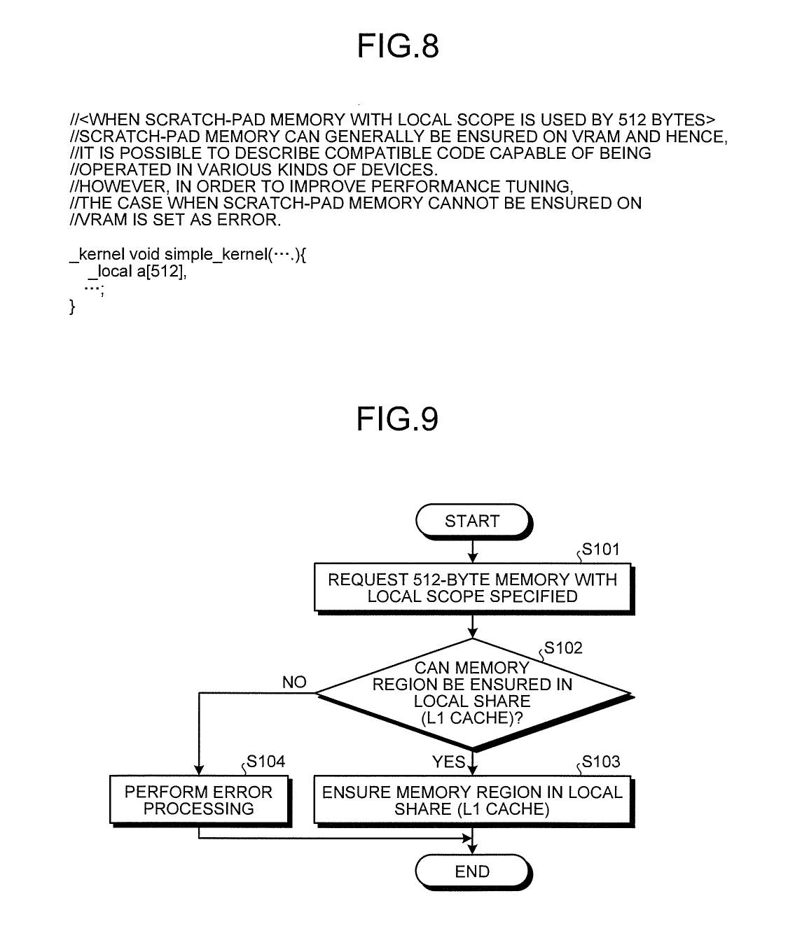

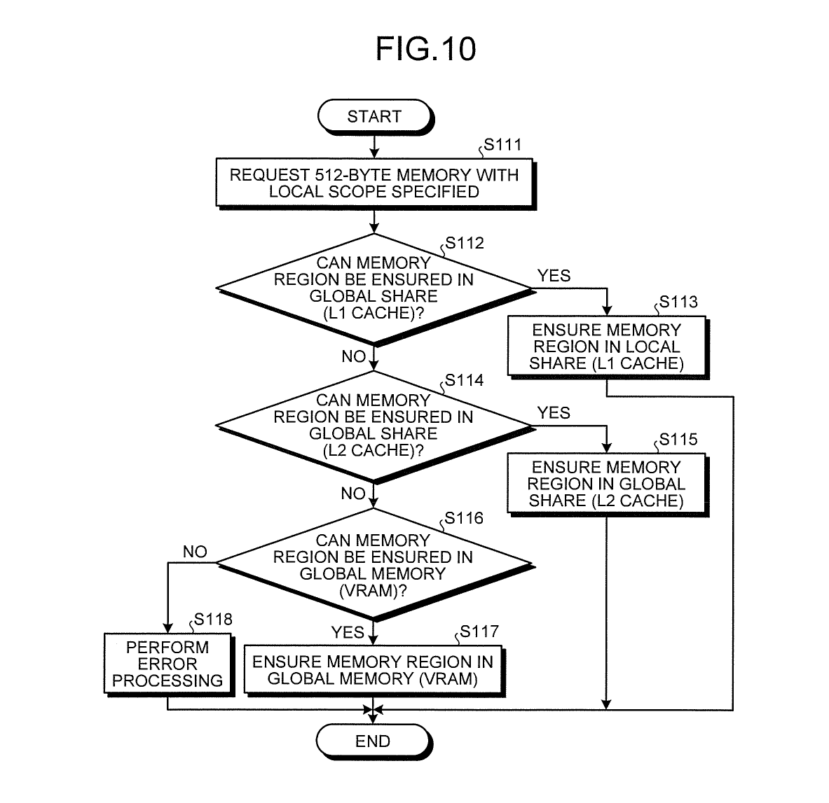

Next, the difference of the behavior of the OpenCL runtime or OpenCL compiler between a case in which code using a 512-byte scratch-pad memory with a local scope is interpreted by the existing OpenCL and a case in which the code is interpreted by the OpenCL in the embodiment is explained. FIG. 8 is a view illustrating the code described when the 512-byte scratch-pad memory with the local scope is used. Here, the code illustrated in FIG. 8 is described not only by using the existing OpenCL but also by the OpenCL in the embodiment. FIG. 9 is a flowchart illustrating the behavior of the OpenCL runtime or the OpenCL compiler when the code illustrated in FIG. 8 is interpreted by the existing OpenCL. FIG. 10 is a flowchart illustrating the behavior of the OpenCL runtime or the OpenCL compiler when the code illustrated in FIG. 8 is interpreted by the OpenCL in the embodiment.

In the case where the code illustrated in FIG. 8 is interpreted by the existing OpenCL as illustrated in FIG. 9, when a memory region of 512 bytes is requested with a local scope (_local a[512]) specified (S101), the OpenCL runtime or the OpenCL compiler determines whether a memory region of 512 bytes can be ensured in the local share 131 in the local memory 130 (S102). When the memory region requested can be ensured in the local share 131 (Yes at S102), the OpenCL runtime or the OpenCL compiler ensures the memory region requested in the local share 131 (S103), and the operation is finished. Furthermore, when the memory region requested cannot be ensured in the local share 131 (No at S102), the OpenCL runtime or the OpenCL compiler performs error processing (S104), and the operation is finished. Here, in the error processing, a programmer may be notified of the fact that it is impossible to compile the code or to ensure the memory region requested in the local share 131.

On the other hand, in the case in which the code illustrated in FIG. 8 is interpreted by the OpenCL in the embodiment as illustrated in FIG. 10, when a memory region of 512 bytes is requested with a local scope (_local a[512]) specified (S111), the OpenCL runtime or the OpenCL compiler first determines whether a memory region of 512 bytes can be ensured in the local share 131 (S112). When the memory region can be ensured (Yes at S112), the OpenCL runtime or the OpenCL compiler ensures the memory region requested in the local share 131 (S113), and the operation is finished. Furthermore, when the memory region requested cannot be ensured in the local share 131 (No at S112), the OpenCL runtime or the OpenCL compiler next determines whether the memory region requested can be ensured in the global share 140 (S114). When the memory region can be ensured (Yes at S114), the OpenCL runtime or the OpenCL compiler ensures the memory region requested in the global share 140 (S115), and the operation is finished. Furthermore, when the memory region requested cannot also be ensured in the global share 140 (No at S114), the OpenCL runtime or the OpenCL compiler determines whether the memory region requested can be ensured in the global memory 20 (S116). When the memory region can be ensured (Yes at S116), the OpenCL runtime or the OpenCL compiler ensures the memory region requested in the global memory 20 (S117), and the operation is finished. In addition, when the memory region requested cannot also be ensured in the global memory 20 (No at S116), the OpenCL runtime or the OpenCL compiler performs error processing (S118), and the operation is finished.

As mentioned above, in the embodiment, the physical allocation with the local scope (_local a[512]) specified is not restricted and hence, even when the memory region requested cannot be ensured in the local share (L1 cache) 131, it is possible to ensure the memory region alternatively in the other physical allocation (the global share 140 or the global memory 20). As a result, it is possible to describe code compatible with various devices.

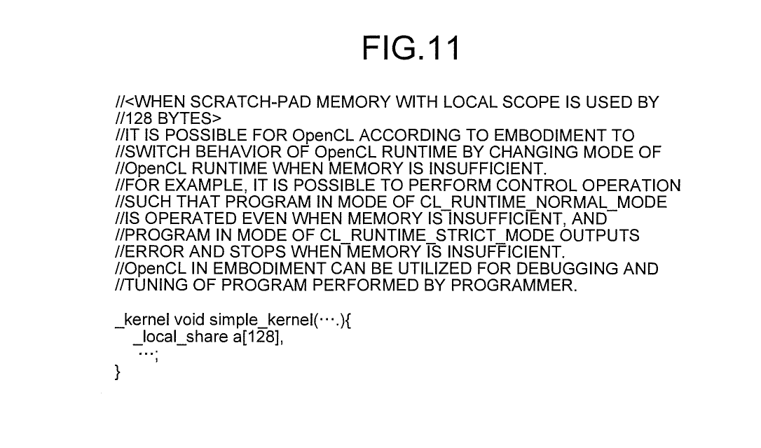

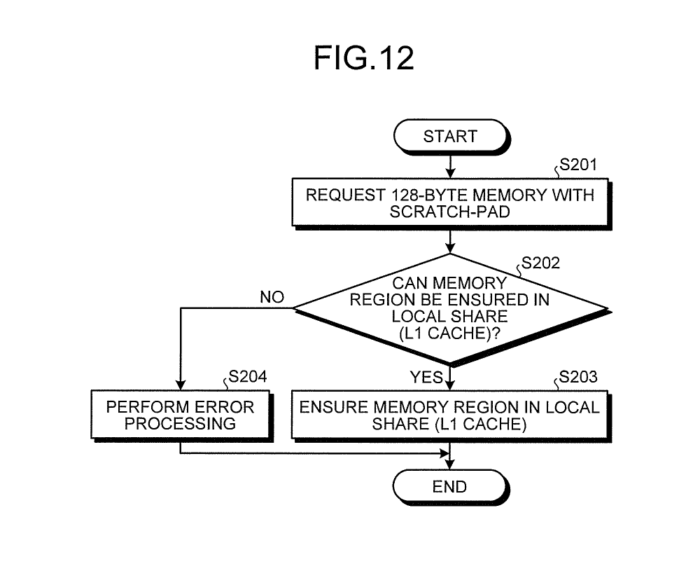

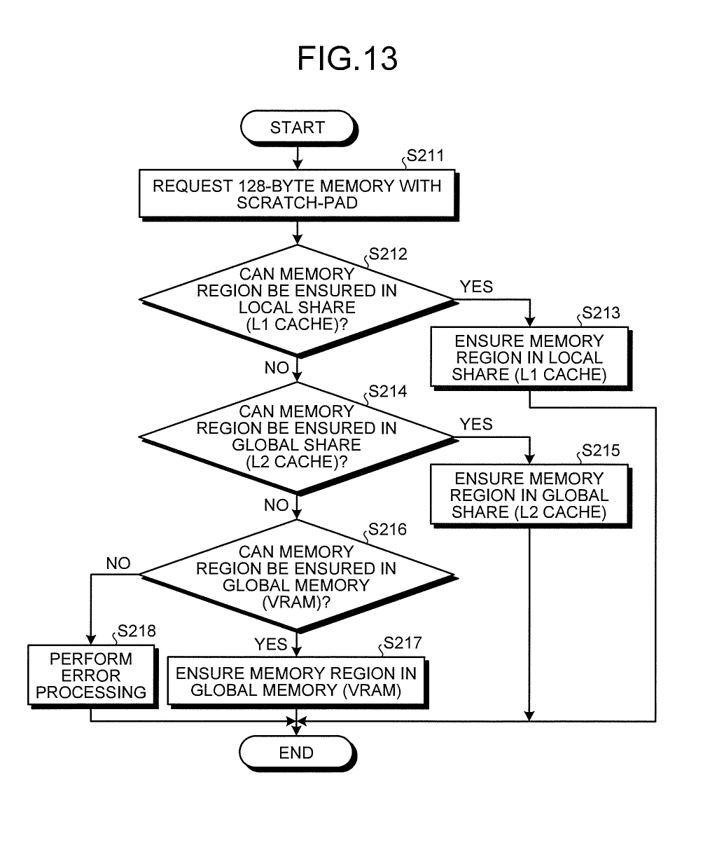

Next, the difference of the behavior of the OpenCL runtime in every mode when a 128-byte scratch-pad memory with a local scope is used is explained. FIG. 11 a view illustrating code described when the 128-byte scratch-pad memory with the local scope is used. FIG. 12 is a flowchart illustrating the behavior of the OpenCL runtime or the OpenCL compiler when the OpenCL runtime is placed in the mode of CL_RUNTIME_STRICT_MODE. FIG. 13 is a flowchart illustrating the behavior of the OpenCL runtime or the OpenCL compiler when the OpenCL runtime is placed in the mode of CL_RUNTIME_NORMAL_MODE.

In the case where the OpenCL runtime is placed in the mode of CL_RUNTIME_STRICT_MODE as illustrated in FIG. 12, when a memory region of 128 bytes is requested with a local scope (_local_share a[128]) specified (S201), the OpenCL runtime or the OpenCL compiler that has interpreted the code illustrated in FIG. 11 first determines whether a memory region of 128 bytes can be ensured in the local share 131 in the local memory 130 (S202). When the memory region requested can be ensured in the local share 131 (Yes at S202), the OpenCL runtime or the OpenCL compiler ensures the memory region requested in the local share 131 (S203), and the operation is finished. Furthermore, when the memory region requested cannot be ensured in the local share 131 (No at S202), the OpenCL runtime or the OpenCL compiler performs error processing (S204), and the operation is finished.

On the other hand, in the case where the OpenCL runtime is placed in a mode of CL_RUNTIME_NORMAL_MODE as illustrated in FIG. 13, when a memory region of 128 bytes is requested with a local scope (_local_share a[128]) specified (S211), the OpenCL runtime or the OpenCL compiler that has interpreted the code illustrated in FIG. 11 first determines whether a memory region of 128 bytes can be ensured in the local share 131 (S212). When the memory region can be ensured (Yes at S212), the OpenCL runtime or the OpenCL compiler ensures the memory region requested in the local share 131 (S213), and the operation is finished. Furthermore, when the memory region requested cannot be ensured in the local share 131 (No at S212), the OpenCL runtime or the OpenCL compiler next determines whether the memory region requested can be ensured in the global share 140 (S214). When the memory region can be ensured (Yes at S214), the OpenCL runtime or the OpenCL compiler ensures the memory region requested in the global share 140 (S215), and the operation is finished. Furthermore, when the memory region requested cannot also be ensured in the global share 140 (No at S214), the OpenCL runtime or the OpenCL compiler determines whether the memory region requested can be ensured in the global memory 20 (S216). When the memory region can be ensured (Yes at S216), the OpenCL runtime or the OpenCL compiler ensures the memory region requested in the global memory 20 (S217), and the operation is finished. In addition, when the memory region requested cannot also be ensured in the global memory 20 (No at S216), the OpenCL runtime or the OpenCL compiler performs error processing (S218), and the operation is finished.

As mentioned above, in the embodiment, it is possible to switch the behavior of the OpenCL runtime in accordance with a mode set to the OpenCL runtime. For example, in the examples illustrated in FIGS. 11 to 13, it is possible to change the behavior of the OpenCL runtime when the memory region required cannot be ensured in the physical allocation with the local scope (_local_share a[128]) specified in accordance with the mode set to the OpenCL runtime. This function is effective for debugging or performance tuning by a programmer.

As mentioned above, in the memory-model processor-model 1 comprising the multistage cache structure constituted of the L1 cache and the L2 cache in the embodiment, it is possible to describe an OpenCL program comprised of code capable of specifically utilizing these cache memories. Furthermore, according to the embodiment, it is possible to describe the OpenCL program by separately defining a variable scope derived from a logical memory model stated in the OpenCL and a memory size capable of being physically allocated depending on actual hardware. As a result, according to the embodiment, it is possible to describe an OpenCL program whose operation is guaranteed irrespective of the size of a physical memory mounted on hardware. In addition, it is possible to describe an OpenCL program being also highly compatible with different hardware.

Furthermore, according to the OpenCL in the embodiment, it is possible to easily describe an OpenCL program corresponding to hardware configurations thus describing an OpenCL program by which specific hardware can exhibit higher performance.

In addition, according to the embodiment, even when only a logical scope defined as in a workgroup is required and code that does not necessarily require high performance is described, it is possible to describe code with a scope restricted as intended by a programmer. As a result, it is possible to improve the readability and development efficiency of a program.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information processor configured to execute a code described in Open Computing Language (OpenCL), the information processor comprising:
a first cache with local scope and configured to be capable of being referred to by all work items in one workgroup;
a second cache with global scope and configured to be capable of being referred to by all work items in a plurality of workgroups;
a global memory with global scope and configured to be capable of being referred to by all work items in a plurality of workgroups; and
an arithmetic module configured to execute a code referring to the second cache as a scratch-pad memory.

2. The information processor of claim 1, wherein
the code is described so as to distinguish and refer to the first cache and the second cache as different scratch-pad memories from each other, and
the arithmetic module is configured to distinguish and refer to the first cache and the second cache as different scratch-pad memories from each other, based on the code.

3. The information processor of claim 2, wherein the code comprises at least one of:
a first code with local scope configured to refer to the first cache as a scratch-pad memory; and
a second code with global scope configured to refer to the second cache as a scratch-pad memory.

4. The information processor of claim 1, wherein the arithmetic module is configured to secure a memory space requested by the code in the first cache or the global memory if the requested memory space cannot be secured in the second cache.

5. The information processor of claim 4, further comprising
a first mode and a second mode as modes for OpenCL runtime, wherein
the arithmetic module is configured to secure a memory space requested by the code in the first cache or the global memory if the first mode is set as well as the requested memory space cannot be secured in the second cache, and to determine that an error is occurred if the second mode is set as well as the requested memory space cannot be secured in the second cache.

6. The information processor of claim 1, wherein the global memory as a physical allocation is a video random access memory (VRAM).

7. An information processing method performed by an information processor configured to execute a code described in Open Computing Language (OpenCL), the information processor comprising: a first cache with local scope and configured to be capable of being referred to by all work items in one workgroup; a second cache with global scope and configured to be capable of being referred to by all work items in a plurality of workgroups; and a global memory with global scope and configured to be capable of being referred to by all work items in a plurality of workgroups, the information processing method comprising:
executing a code referring to the second cache as a scratch-pad memory.

8. An information processor configured to execute a code described in Open Computing Language (OpenCL), wherein the code comprises at least one of:
a first code with local scope configured not to limit physical allocation; and
a second code with global scope configured to specify a global memory as physical allocation.
